(19) United States
(12) Patent Application Publication
(10) Pub. No.: US 2024/0357895 A1
(43) Pub. Date: Oct. 24, 2024

(54) Display Substrate, Display Device and Manufacturing Method of Display Substrate

(71) Applicants: Chengdu BOE Optoelectronics Technology Co., Ltd.; BOE Technology Group Co., Ltd.

(72) Inventors: Lulin MA, Beijing (CN); Jaeho LEE, Beijing (CN); Cheng ZENG, Beijing (CN); Zhen SUN, Beijing (CN); Hongwei ZHANG, Beijing (CN); Zhenye WEI, Beijing (CN); Qiyun WANG, Beijing (CN)

(21) Appl. No.: 18/039,278

(22) PCT Filed: Dec. 29, 2021
(86) PCT No.: PCT/CN2021/142661

§ 371 Date: May 29, 2023

(51) Int. Cl. H10K 59/35; H10K 50/115; H10K 59/38; H10K 59/80

(52) U.S. Cl. CPC H10K 59/35; H10K 50/115; H10K 59/38; H10K 59/873

(57) ABSTRACT

A display substrate includes multiple light emitting devices disposed on a base substrate for emitting light of a third color, and a first encapsulation structure layer and a light conversion layer sequentially stacked on a side of the multiple light emitting devices away from the base substrate; the light conversion layer includes a first quantum dot material emitting light of a first color after receiving the light of the third color emitted by the light emitting devices and a second quantum dot material emitting light of a second color after receiving the light of the third color emitted by the light emitting devices. The first encapsulation structure layer includes a first inorganic encapsulation layer, an organic encapsulation layer, and a second inorganic encapsulation layer that are sequentially stacked in a direction away from the base substrate; the organic encapsulation layer includes an organic encapsulation material and a dye.

### CROSS-REFERENCE TO RELATED APPLICATION

The present application is a U.S. National Phase Entry of International Application PCT/CN2021/142661 having an international filing date of Dec. 29, 2021, and entitled “Display Substrate, Display Device and Manufacturing Method of Display Substrate”, the contents of the above-identified application are incorporated herein by reference.

### TECHNICAL FIELD

Embodiments of the present disclosure relate to, but are not limited to, the field of display technology, in particular to a display substrate, a display device, and a method for manufacturing a display substrate.

### BACKGROUND

Organic light emitting diode (OLED) devices have advantages such as self-luminescence, high contrast, wide viewing angle, high response speed, lightness, thinness, and foldability. Quantum dot (QD) is a kind of nanoscale semiconductor material with core and shell. When a certain light or voltage is applied to it, it will emit light with a specific frequency. The frequency of the light is related to a size of a quantum dot. A quantum dot has advantages of narrow emission spectrum, wide adjustable color range and long fluorescence lifetime. Because of a solution preparation process of a quantum dot, it can be prepared by a liquid-based method such as inkjet printing, which has low manufacturing cost and wide application prospects.

Some QD-OLED display technologies use blue light emitted by blue OLED as backlight to excite quantum dots to emit light and achieve colorization, which can simplify an evaporation process of OLED, reduce evaporation cost, prolong product life and be suitable for large-size display.

### SUMMARY

The following is a summary of subject matters described herein in detail. The summary is not intended to limit the protection scope of claims.

An embodiment of the present disclosure provides a display substrate, which includes a first sub-pixel with emergent light of a first color, a second sub-pixel with emergent light of a second color and a third sub-pixel with emergent light of a third color disposed on the base substrate;
the display substrate includes multiple light emitting devices disposed on the base substrate for emitting light of the third color, and a first encapsulation structure layer and a light conversion layer which are sequentially stacked on a side of the multiple light emitting devices away from the base substrate, and each sub-pixel includes one of the light emitting devices;
the light conversion layer is configured to emit the light of the first color and the light of the second color after receiving the light of the third color emitted by the multiple light emitting devices, the light conversion layer includes a first quantum dot material and a second quantum dot material, the first quantum dot material is configured to emit the light of the first color after receiving the light of the third color emitted by the light emitting devices, and the second quantum dot material is configured to emit the light of the second color after receiving the light of the third color emitted by the light emitting devices;
the first encapsulation structure layer includes a first inorganic encapsulation layer, an organic encapsulation layer, and a second inorganic encapsulation layer that are sequentially stacked in a direction away from the base substrate; the organic encapsulation layer includes an organic encapsulation material and a dye, a color of the dye is the same as that of the light of the third color emitted by the light emitting devices, and a peak wavelength of emergent light of the third color after the light of the third color emitted by the light emitting devices passes through the organic encapsulation layer is different from a peak wavelength of the light of the third color emitted by the light emitting devices.

An embodiment of the present disclosure further provides a display device including the display substrate described above.

An embodiment of the present disclosure further provides a method for manufacturing a display substrate, including:
forming a drive structure layer on a base substrate, wherein the drive structure layer includes a pixel drive circuit;
forming multiple light emitting devices emitting light of a third color on a side of the drive structure layer away from the base substrate, the light emitting devices are electrically connected with the pixel drive circuit;
forming a first inorganic encapsulation layer, an organic encapsulation layer and a second inorganic encapsulation layer sequentially on a side of the multiple light emitting devices away from the base substrate; wherein the organic encapsulation layer includes an organic encapsulation material and a dye, a color of the dye is the same as that of the light of the third color emitted by the light emitting devices, and a peak wavelength of emergent light of the third color after the light of the third color emitted by the light emitting devices passes through the organic encapsulation layer is different from a peak wavelength of the light of the third color emitted by the light emitting devices; the organic encapsulation layer is formed by an ink jet printing process;
a light conversion layer is formed on a side of the second inorganic encapsulation layer away from the base substrate, wherein the light conversion layer is configured to emit the light of the first color and the light of the second color after receiving the light of the third color emitted by the multiple light emitting devices, the light conversion layer includes a first quantum dot material and a second quantum dot material, the first quantum dot material is configured to emit the light of the first color after receiving the light of the third color emitted by the light emitting devices, and the second quantum dot material is configured to emit the light of the second color after receiving the light of the third color emitted by the light emitting devices.

Other aspects may be understood upon reading and understanding the drawings and detailed description.

### BRIEF DESCRIPTION OF DRAWINGS

Accompanying drawings are intended to provide a further understanding of technical solutions of the present disclosure and constitute a part of the specification, and are used for explaining the technical solutions of the present disclosure together with embodiments of the present disclosure, and do not constitute limitations on the technical solutions of the present disclosure. Shapes and sizes of components in the drawings do not reflect actual scales, and are only intended to schematically illustrate contents of the present disclosure.

FIG. 1 is a schematic view of a partial cross-sectional structure of a display substrate according to some exemplary embodiments.

FIG. 2 is a schematic view of a partial cross-sectional structure of a display substrate according to some other exemplary embodiments.

FIG. 3 is a schematic view of a partial cross-sectional structure of a display substrate according to some other exemplary embodiments.

FIG. 4a is a schematic diagram of a structure of a prism layer of a display substrate according to some exemplary embodiments.

FIG. 4b is a schematic front view of the structure of the prism layer of FIG. 4a in some exemplary embodiments.

FIG. 4c is a schematic side view of the structure of the prism layer of FIG. 4a in some exemplary embodiments.

FIG. 5a is a schematic diagram of a structure of a prism layer of a display substrate according to some other exemplary embodiments.

FIG. 5b is a schematic front view of the structure of the prism layer of FIG. 5a in some exemplary embodiments.

FIG. 5c is a schematic side view of the structure of the prism layer of FIG. 5a in some exemplary embodiments.

FIG. 6a is a schematic diagram of a structure of a first light modulation layer of a display substrate according to some exemplary embodiments.

FIG. 6b is a schematic diagram of a structure of a first light modulation layer of a display substrate according to some other exemplary embodiments.

FIG. 6c is a schematic diagram of a structure of a first light modulation layer of a display substrate according to some other exemplary embodiments.

FIG. 6d is a schematic diagram of a structure of a first light modulation layer of a display substrate according to some other exemplary embodiments.

FIG. 7a is a schematic diagram of a structure of a second light modulation layer of a display substrate according to some exemplary embodiments.

FIG. 7b is a schematic diagram of a structure of a second light modulation layer of a display substrate according to some other exemplary embodiments.

FIG. 7c is a schematic diagram of a structure of a second light modulation layer of a display substrate according to some other exemplary embodiments.

FIG. 7d is a schematic diagram of a structure of a second light modulation layer of a display substrate according to some other exemplary embodiments.

FIG. 8 is a curve graph showing change of brightness with respect to a viewing angle of a display substrate according to some exemplary embodiments.

FIG. 9 is a curve graph showing change of brightness with respect to a viewing angle of a display substrate according to some other exemplary embodiments.

### DETAILED DESCRIPTION

Those of ordinary skills in the art should understand that modifications or equivalent replacements may be made to the technical solutions of embodiments of the present disclosure without departing from the spirit and scope of the technical solutions of the embodiments of the present disclosure, and should all fall in the scope of the claims of the present disclosure.

An embodiment of the present disclosure provides a display substrate, which includes a first sub-pixel with emergent light of a first color, a second sub-pixel with emergent light of a second color and a third sub-pixel with emergent light of a third color disposed on a base substrate.

The display substrate includes multiple light emitting devices disposed on the base substrate for emitting light of a third color, and a first encapsulation structure layer and a light conversion layer which are sequentially stacked on a side of the multiple light emitting devices away from the base substrate, and each sub-pixel includes one of the light emitting devices.

The light conversion layer is configured to emit light of the first color and light of the second color after receiving the light of the third color emitted by the multiple light emitting devices, the light conversion layer includes a first quantum dot material and a second quantum dot material, the first quantum dot material is configured to emit light of the first color after receiving the light of the third color emitted by the light emitting devices, and the second quantum dot material is configured to emit light of the second color after receiving the light of the third color emitted by the light emitting devices.

The first encapsulation structure layer includes a first inorganic encapsulation layer, an organic encapsulation layer, and a second inorganic encapsulation layer that are sequentially stacked in a direction away from the base substrate. The organic encapsulation layer includes an organic encapsulation material and a dye, and a color of the dye is the same as that of the light of the third color emitted by the light emitting devices. A peak wavelength of emergent light of the third color after the light of the third color emitted by the light emitting devices passes through the organic encapsulation layer is different from a peak wavelength of the light of the third color emitted by the light emitting devices.

In the display substrate of the embodiment of the present disclosure, the dye is added into the organic encapsulation layer, and the color of the dye is the same as that of the light of the third color emitted by the light emitting devices, and the peak wavelength of emergent light of the third color after the light of the third color emitted by the light emitting device passes through the organic encapsulation layer is different from the peak wavelength of the light of the third color emitted by the light emitting devices, that is, the peak wavelength of light of the third color emitted by the light emitting devices can be changed by the added dye, so that chroma of the light of the third color emitted by the light emitting devices can be improved, and a light emitting efficiency and color gamut of the display substrate can be improved.

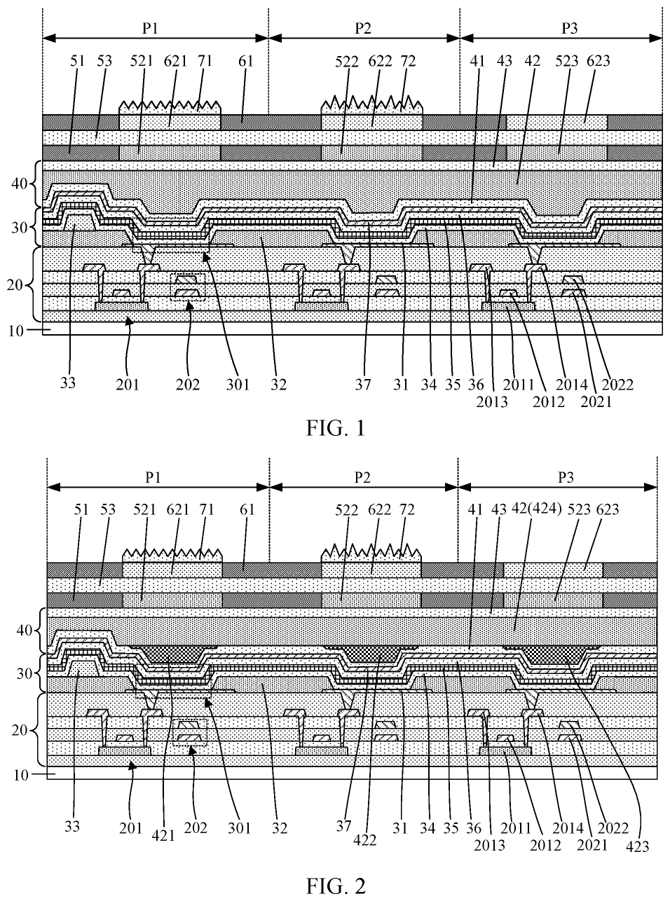

In some exemplary embodiments, as shown in FIG. 1, FIG. 1 is a schematic view of a partial cross-sectional structure of a display substrate according to some exemplary embodiments. The display substrate includes a first sub-pixel P1 with emergent light of a first color, a second sub-pixel P2 with emergent light of a second color, and a third sub-pixel P3 with emergent light of a third color disposed on a base substrate 10. Exemplarily, the light of the first color may be red light, the light of the second color may be green light, and the light of the third color may be blue light.

The display substrate includes multiple light emitting devices 301 disposed on the base substrate 10 for emitting light of the third color, and a first encapsulation structure layer 40 and a light conversion layer which are sequentially stacked on a side of the multiple light emitting devices 301 away from the base substrate 10. Each sub-pixel includes one of the light-emitting devices 301. Exemplarily, the light emitting devices 301 may be blue organic light emitting diode (blue OLED) devices or blue light emitting diode (LED) devices.

The light conversion layer includes a first quantum dot layer 521 located in the first sub-pixel P1, a second quantum dot layer 522 located in the second sub-pixel P2, and a light transmissive layer 523 located in the third sub-pixel P3. The first quantum dot layer 521 is configured to receive light of the third color emitted by the light emitting device 301 of the first sub-pixel P1 and then emit light of the first color, the second quantum dot layer 522 is configured to receive light of the third color emitted by the light emitting device 301 of the second sub-pixel P2 and then emit light of the second color, and the light transmissive layer 523 is configured to emit light of the third color after light of the third color emitted by the light emitting device 301 of the third sub-pixel P3 passes through the light transmissive layer 523. The light transmissive layer 523 may include scattering particles and may cause the light emitted from the light emitting devices 301 to be emitted at multiple angles.

The first encapsulation structure layer 40 includes a first inorganic encapsulation layer 41, an organic encapsulation layer 42 and a second inorganic encapsulation layer 43 that are stacked sequentially along a direction away from the base substrate 10. The first encapsulation structure layer 40 can prevent external water and oxygen from invading the light emitting devices 301, thereby ensuring performance of the light emitting devices 301. A material of the organic encapsulation layer 42 may include a mixed material of an organic encapsulation material and a dye and the material of the organic encapsulation layer 42 of each sub-pixel may be the same. One or more dyes may be provided. Exemplarily, a peak wavelength of emergent light after the light of the third color emitted by the light emitting devices 301 passes through the organic encapsulation layer 42 may be made a desired target peak wavelength by changing a type and a concentration of the dye, so that the chroma of the light of the third color emitted by the light emitting devices 301 can be improved, and the light emitting efficiency and the color gamut of the display substrate can be improved.

In some other exemplary embodiments, as shown in FIG. 2, FIG. 2 is a schematic view of a partial cross-sectional structure of a display substrate according to some other exemplary embodiments. The display substrate includes a first sub-pixel P1 with emergent light of a first color, a second sub-pixel P2 with emergent light of a second color, and a third sub-pixel P3 with emergent light of a third color disposed on a base substrate 10. Exemplarily, the light of the first color may be red light, the light of the second color may be green light, and the light of the third color may be blue light.

The display substrate includes multiple light emitting devices 301 disposed on the base substrate 10 for emitting light of the third color, and a first encapsulation structure layer 40 and a light conversion layer which are sequentially stacked on a side of the multiple light emitting devices 301 away from the base substrate 10. Each sub-pixel includes one of the light emitting devices 301. Exemplarily, the light emitting device 301 may be a blue OLED device or a blue light emitting diode (LED) device.

The light conversion layer includes a first quantum dot layer 521 located in the first sub-pixel P1, a second quantum dot layer 522 located in the second sub-pixel P2, and a light transmissive layer 523 located in the third sub-pixel P3. The first quantum dot layer 521 is configured to receive light of the third color emitted by the light emitting device 301 of the first sub-pixel P1 and then emit light of the first color, the second quantum dot layer 522 is configured to receive light of the third color emitted by the light emitting device 301 of the second sub-pixel P2 and then emit light of the second color, and the light transmissive layer 523 is configured to emit light of the third color after light of the third color emitted by the light emitting device 301 of the third sub-pixel P3 passes through the light transmissive layer 523. The light transmissive layer 523 may include scattering particles and may cause the light emitted from the light emitting devices 301 to be emitted at multiple angles.

The first encapsulation structure layer 40 includes a first inorganic encapsulation layer 41, an organic encapsulation layer 42 and a second inorganic encapsulation layer 43 that are stacked sequentially along a direction away from the base substrate 10. The first encapsulation structure layer 40 can prevent external water and oxygen from invading the light emitting devices 301, thereby ensuring the performance of the light emitting devices 301. The organic encapsulation layer 42 includes a first dye in the first sub-pixel P1, a second dye in the second sub-pixel P2, and a third dye in the third sub-pixel P3. A peak wavelength of emergent light after the light of the third color emitted by the light emitting device 301 of the first sub-pixel P1 passes through the organic encapsulation layer 42 of the first sub-pixel P1 is λ1, a peak wavelength of emergent light after the light of the third color emitted by the light emitting device 301 of the second sub-pixel P2 passes through the organic encapsulation layer 42 of the second sub-pixel P2 is λ2, and a peak wavelength of emergent light after the light of the third color emitted by the light emitting device 301 of the third sub-pixel P3 passes through the organic encapsulation layer 42 of the third sub-pixel P3 is λ3, wherein λ1, λ2 and λ3 are not equal to each other.

Due to differences in absorption of light of the third color with different peak wavelengths between the first quantum dot layer 521 and the second quantum dot layer 522, in this embodiment, different dyes are added in the organic encapsulation layers 42 of the sub-pixels with different colors, and after the light of the third color emitted by the light emitting devices 301 of the sub-pixels with different colors passes through the organic encapsulation layer 42, the peak wavelengths of emergent light are different. In this way, different dyes may be added to make the peak wavelengths of emergent light after the light of the third color emitted by the light emitting devices 301 of sub-pixels with different colors passes through the organic encapsulation layer 42 be different target peak wavelengths as required, in order to match optimal excitation wavelengths of the first quantum dot layer 521 of the first sub pixel P1 and the second quantum dot layer 522 of the second sub pixel P2 respectively, and improve the chroma of the light of the third color emitted by the light emitting device 301 of the third sub-pixel P3, thereby improving the light emitting efficiency and the color gamut of the display substrate.

In an example of this embodiment, as shown in FIG. 2, a surface of the first inorganic encapsulation layer 41 away from the base substrate 10 may be provided with a first groove in the first sub-pixel P1, a second groove in the second sub-pixel P2, and a third groove in the third sub-pixel P3. Exemplarily, the first groove, the second groove, and the third groove may be formed using an etching process.

The organic encapsulation layer 42 may include a mixed material layer. The mixed material layer includes a first mixed material 421 disposed in the first groove, a second mixed material 422 disposed in the second groove, and a third mixed material 423 disposed in the third groove. The first mixed material 421 includes the organic encapsulation material and the first dye, the second mixed material 422 includes the organic encapsulation material and the second dye, and the third mixed material 423 includes the organic encapsulation material and the third dye.

The organic encapsulation layer 42 may further include a film layer 424 formed of the organic encapsulation material disposed on a side of the mixed material layer away from the base substrate 10.

In some exemplary embodiments, as shown in FIG. 1 and FIG. 2, the display substrate may further include a first black matrix layer 51 disposed on a side of the first encapsulation structure layer 40 away from the base substrate 10. The first black matrix layer 51 is provided with multiple first openings, each of the first openings and the light emitting device 301 of each corresponding sub-pixel are oppositely disposed. The first quantum dot layer 521, the second quantum dot layer 522 and the light transmissive layer 523 are respectively disposed in the corresponding first openings.

In some other exemplary embodiments, as shown in FIG. 3, FIG. 3 is a schematic view of a partial cross-sectional structure of a display substrate according to some other exemplary embodiments. The display substrate includes a first sub-pixel P1 with emergent light of a first color, a second sub-pixel P2 with emergent light of a second color, and a third sub-pixel P3 with emergent light of a third color disposed on a base substrate 10. Exemplarily, the light of the first color may be red light, the light of the second color may be green light, and the light of the third color may be blue light.

The display substrate includes multiple light emitting devices 301 disposed on the base substrate 10 for emitting light of the third color, and a first encapsulation structure layer 40 and a light conversion layer 52 sequentially stacked on a side of the multiple light emitting devices 301 away from the base substrate 10. Each sub-pixel includes one of the light emitting devices 301. Exemplarily, the light emitting device 301 may be a blue OLED device or a blue light emitting diode (LED) device.

The light conversion layer 52 has an integral structure, i.e. a film layer of the light conversion layer 52 is a continuous film layer in a display area. The light conversion layer 52 is configured to emit light of the first color and light of the second color after receiving the light of the third color emitted by the multiple light emitting devices 301. The light conversion layer 52 includes a first quantum dot material configured to emit light of the first color after receiving the light of the third color emitted by the light emitting devices 301 and a second quantum dot material configured to emit light of the second color after receiving the light of the third color emitted by the light emitting devices 301. The light of the first color emitted by the first quantum dot material, the light of the second color emitted by the second quantum dot material, and the light of the third color emitted by the light emitting devices 301 through the light conversion layer 52 are mixed to form white light.

The first encapsulation structure layer 40 includes a first inorganic encapsulation layer 41, an organic encapsulation layer 42 and a second inorganic encapsulation layer 43 that are stacked sequentially along a direction away from the base substrate 10. The first encapsulation structure layer 40 can prevent external water and oxygen from invading the light emitting devices 301, thereby ensuring the performance of the light emitting devices 301. A material of the organic encapsulation layer 42 may include a mixed material of the organic encapsulation material and the dye and the material of the organic encapsulation layer 42 of each sub-pixel may be the same. The dyes may be one or more. Exemplarily, the peak wavelength of light of the third color emitted by the light emitting device 301 after passing through the organic encapsulation layer 42 can be made a desired target peak wavelength by changing the type and concentration of the dye, so that the chroma of the light of the third color emitted by the light emitting device 301 can be improved, and the light emitting efficiency and the color gamut of the display substrate can be improved.

In some exemplary embodiments, as shown in FIG. 1, FIG. 2 and FIG. 3, the materials of the first inorganic encapsulation layer 41 and the second inorganic encapsulation layer 43 may be any one or more of silicon nitride, silicon oxide, and silicon oxynitride. The first inorganic encapsulation layer 41 and the second inorganic encapsulation layer 43 may be formed by a process such as plasma enhanced chemical vapor deposition (PECVD), atomic layer deposition (ALD), etc.

In some exemplary embodiments, as shown in FIG. 1, FIG. 2 and FIG. 3, the display substrate may further include a color filter layer disposed on a side of the light conversion layer away from the base substrate 10. The color filter layer includes a first filter unit 621 located in the first sub-pixel P1, a second filter unit 622 located in the second sub-pixel P2, and a third filter unit 623 located in the third sub-pixel P3. The first filter unit 621 is configured to filter and emit light of the first color, the second filter unit 622 is configured to filter and emit light of the second color, and the third filter unit 623 is configured to filter and emit light of the third color.

The display substrate may further include a second black matrix layer 61 disposed on a side of the light conversion layer away from the base substrate 10. The second black matrix layer 61 is provided with multiple second openings. Each of the second openings and the light emitting device 301 of each corresponding sub-pixel are oppositely disposed. The first filter unit 621, the second filter unit 622, and the third filter unit 623 are respectively disposed in corresponding second openings.

The display substrate may further include a second encapsulation structure layer 53 disposed between the light conversion layer and the color filter layer. A material of the second encapsulation structure layer 53 may be an inorganic material or an organic material, for example, any one or more of organic resin, silicon nitride, silicon oxide, and silicon oxynitride. The second encapsulation structure layer 53 can protect the light conversion layer from external water and oxygen corrosion.

In some exemplary embodiments, as shown in FIG. 1, FIG. 2 and FIG. 3, the display substrate further includes a drive structure layer 20 and a light emitting structure layer 30 which are sequentially stacked on the base substrate 10. The drive structure layer 20 may include multiple pixel drive circuits, and the light emitting structure layer 30 includes multiple light emitting devices 301. The light emitting devices 301 may be blue OLED devices, and each of the light emitting devices 301 is connected to one corresponding pixel drive circuit. The pixel drive circuit may include multiple thin film transistors 201 and a storage capacitor 202, and the pixel drive circuit may have a structure of 3T1C, 4T1C, 5T1C, 5T2C, 6T1C, 7T1C, or the like, which is not limited in the embodiments of the present disclosure.

The light emitting structure layer 30 may include a first electrode layer, a pixel definition layer 32, an organic functional layer and a second electrode layer 37. The first electrode layer includes multiple first electrodes 31 disposed on the drive structure layer 20. Each of the first electrodes 31 is connected to one of the pixel drive circuits, and each of the pixel drive circuits drives a corresponding one of the light emitting devices 301 to emit light. The pixel definition layer 32 is disposed on a side of the multiple first electrodes 31 away from the base substrate 10 and is provided with multiple pixel openings. Each pixel opening exposes a surface of a corresponding one of the first electrodes 31 away from the base substrate 10. The organic functional layer may include a first organic structure layer 34, an organic light emitting layer 35, and a second organic structure layer 36 which are sequentially stacked on a side of the multiple first electrodes 31 and the pixel definition layer 32 away from the base substrate 10. The first organic structure layer 34 may include any one or more of a hole injection layer, a hole transport layer, and an electron barrier layer. The second organic structure layer 36 may include any one or more of a hole barrier layer, an electron transport layer, and an electron injection layer. Any film layer of the first organic structure layer 34 and the second organic structure layer 36 may be in an integral structure and be a common layer of multiple sub-pixels (or multiple light emitting devices 301). The organic light emitting layer 35 has an integral structure and is a common layer of multiple sub-pixels (or multiple light emitting devices 301). The second electrode layer 37 is stacked on a surface of the organic functional layer away from the base substrate 10. Each of the first electrodes 31, the organic functional layer and the second electrode layer 37 is sequentially stacked to form one light emitting device 301 (such as a blue OLED device), and the organic light emitting layer 35 emits light of a third color under a voltage of the first electrode 31 and the second electrode layer 37. The light emitting structure layer 30 may further include a spacer 33 (PS) disposed on a surface of the pixel definition layer 32 away from the base substrate 10, the spacer 33 may be used for supporting a mask plate when forming a film layer of the organic functional layer by evaporation. In other embodiments, the light emitting device 301 is a blue OLED device, the blue OLED device may have a series (Tandem) structure in order to improve a light emitting efficiency of the blue OLED device.

In some exemplary embodiments, as shown in FIG. 1, FIG. 2 and FIG. 3, the display substrate may further include a light modulation layer disposed on a side of the color filter layer away from the base substrate 10. The light modulation layer includes a first light modulation layer 71 located in the first sub-pixel P1 and a second light modulation layer 72 located in the second sub-pixel P2. The first light modulation layer 71 and the second light modulation layer 72 each include at least one (e.g. one or two) prism layer. The at least one prism layer is configured to converge light emitted from the color filter layer of a sub-pixel where the prism layer is located in a front viewing direction of the display substrate. Because the quantum dots emit light uniformly in all directions, light from some viewing angles cannot be emitted, which will cause loss of light of the display substrate from a front viewing angle. In this embodiment, by disposing the first light modulation layer 71 and the second light modulation layer 72 on the side of the color filter layer away from the base substrate 10, photons with a large viewing angle of the display substrate can be extracted and converged in a front viewing angle direction, and the brightness and color gamut of the display substrate can be improved from the front viewing angle.

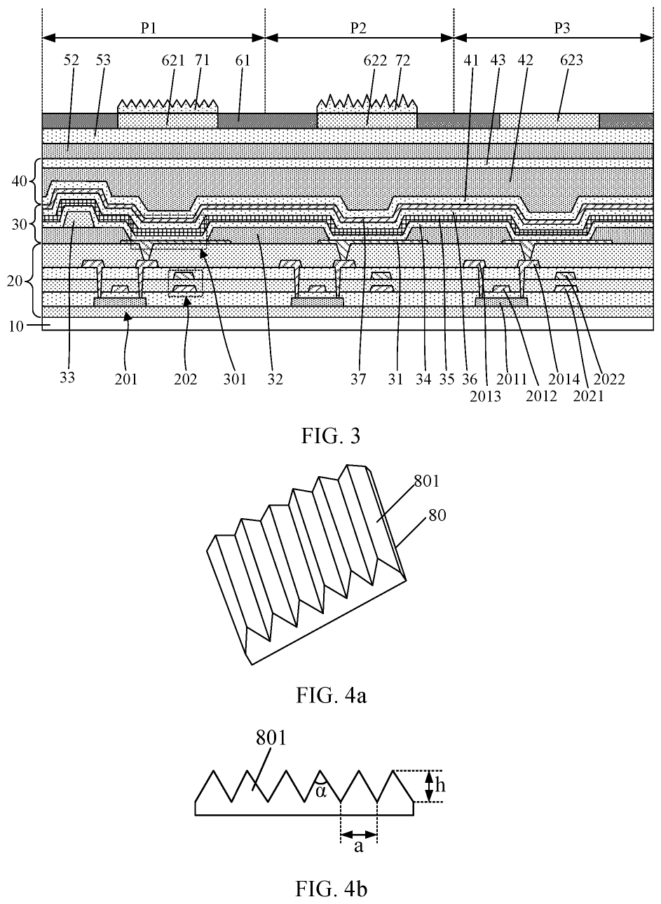

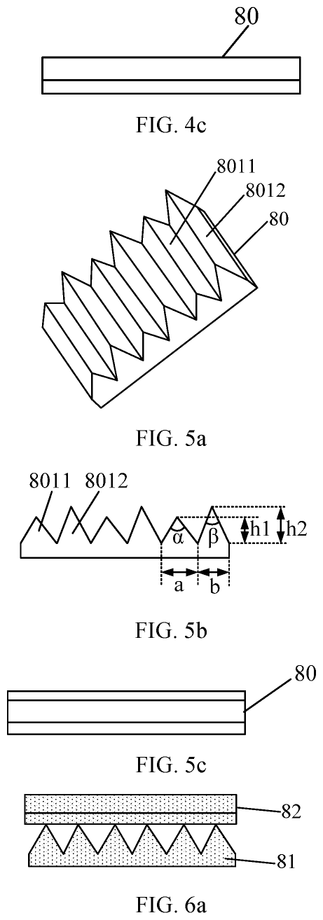

In one example of this embodiment, as shown in FIG. 4a, FIG. 4b and FIG. 4c, FIG. 4a is a schematic diagram of a structure of a prism layer of a display substrate according to some exemplary embodiments. FIG. 4b is a schematic front view of a structure of the prism layer of FIG. 4a in some exemplary embodiments, and FIG. 4c is a schematic side view of a structure of the prism layer of FIG. 4a in some exemplary embodiments. The prism layer 80 may include multiple microprisms 801 disposed in parallel, and shapes and sizes of cross sections of the multiple microprisms 801 may be the same.

Exemplarily, as shown in FIG. 4b, the multiple microprisms 801 protrude toward a side of the prism layer 80 away from the base substrate. A cross-sectional shape of each of the microprisms 801 may be an isosceles triangle, and the isosceles triangle may have an apex angle α of 60° to 120°, a bottom edge length a of 20 um to 30 um, and a height h of 12 um to 18 um. The prism layer 80 may be made of an organic material such as acrylic resin or epoxy resin.

In another example of this embodiment, as shown in FIG. 5a, FIG. 5b and FIG. 5c, FIG. 5a is a schematic diagram of a structure of a prism layer of a display substrate according to some other exemplary embodiments, FIG. 5b is a schematic front view of a structure of the prism layer of FIG. 5a in some exemplary embodiments, and FIG. 5c is a schematic side view of a structure of the prism layer of FIG. 5a in some exemplary embodiments. The prism layer 80 may include multiple microprisms disposed in parallel, the multiple microprisms may include a first microprism 8011 and a second microprism 8012 disposed alternately, and heights of the first microprism 8011 and the second microprism 8012 are different.

Exemplarily, as shown in FIG. 5b, the multiple microprisms protrude toward the side of the prism layer 80 away from the base substrate. Sectional shapes of the first microprism 8011 and the second microprism 8012 may each be an isosceles triangle. An isosceles triangular section of the first microprism 8011 may have an apex angle α of 60° to 120°, a bottom edge length a of 20 um to 32 um, and a height h1 of 12 um to 18 um. An isosceles triangular section of the second microprism 8012 may have an apex angle β of 60° to 120°, a bottom edge length b of 14 um to 22 um, and a height h2 of 7 um to 12 um. The prism layer 80 may be made of an organic material such as acrylic resin or epoxy resin.

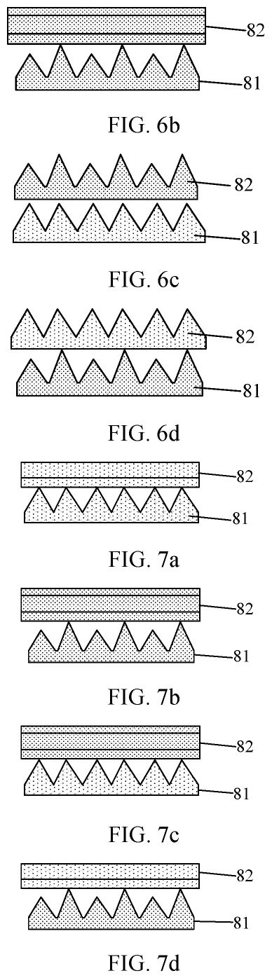

In some exemplary embodiments, the light of the first color is red light, the light of the second color is green light, and the light of the third color is blue light. As shown in FIG. 6a and FIG. 6b, FIG. 6a is a schematic diagram of a structure of a first light modulation layer 71 of a display substrate according to some exemplary embodiments, and FIG. 6b is a schematic diagram of a structure of a first light modulation layer 71 of a display substrate according to some other exemplary embodiments. The first light modulation layer 71 may include a first prism layer 81 and a second prism layer 82 stacked sequentially along a direction away from the base substrate 10. The first prism layer 81 includes multiple microprisms disposed in parallel and extending in a first direction, and the second prism layer 82 includes multiple microprisms disposed in parallel and extending in a second direction, wherein the first direction is perpendicular to the second direction. As shown in FIG. 6a, shapes and sizes of cross sections of the multiple microprisms of the first prism layer 81 may be the same as shapes and sizes of cross sections of the multiple microprisms of the second prism layer 82, and the prism layer of the example of FIG. 4a may be used as each of the first prism layer 81 and the second prism layer 82 in the example of FIG. 6a. Or, as shown in FIG. 6b, the multiple microprisms of the first prism layer 81 and the multiple microprisms of the second prism layer 82 each include first microprisms 8011 and second microprisms 8012 which are alternately disposed, heights of the first microprisms 8011 and the second microprisms 8012 are different, and the prism layer of the example of FIG. 5a may be used as each of the first prism layer 81 and second prism layer 82 in the example of FIG. 6b.

In some exemplary embodiments, the light of the first color is red light, the light of the second color is green light, and the light of the third color is blue light. As shown in FIG. 6c and FIG. 6d, FIG. 6c is a schematic diagram of a structure of a first light modulation layer 71 of a display substrate according to some other exemplary embodiments, and FIG. 6d is a schematic diagram of a structure of a first light modulation layer 71 of a display substrate according to some other exemplary embodiments. The first light modulation layer 71 includes a first prism layer 81 and a second prism layer 82 stacked sequentially in a direction away from the base substrate 10, and the first prism layer 81 and the second prism layer 82 each includes multiple microprisms disposed in parallel and extending in the first direction. Multiple microprisms of one of the first prism layer 81 and the second prism layer 82 have the same sectional shape and size, and multiple microprisms of the other of the first prism layer 81 and the second prism layer 82 include a first microprism 8011 and a second microprism 8012 which are disposed alternately, and heights of the first microprism 8011 and the second microprism 8012 are different. Exemplarily, in the example of FIG. 6c, the prism layer of the example of FIG. 4a may be used as the first prism layer 81 and the prism layer of the example of FIG. 5a may be used as the second prism layer 82. In the example of FIG. 6d, the prism layer of the example of FIG. 5a may be used as the first prism layer 81 and the prism layer of the example of FIG. 4a may be used as the second prism layer 82.

In some exemplary embodiments, the light of the first color is red light, the light of the second color is green light, and the light of the third color is blue light. As shown in FIG. 7a and FIG. 7b, FIG. 7a is a schematic diagram of a structure of a second light modulation layer 72 of a display substrate according to some exemplary embodiments, and FIG. 7b is a schematic diagram of a structure of a second light modulation layer 72 of a display substrate according to some other exemplary embodiments. The second light modulation layer 72 may include a first prism layer 81 and a second prism layer 82 stacked sequentially in a direction away from the base substrate 10. The first prism layer includes multiple microprisms disposed in parallel and extending in a first direction and the second prism layer 82 includes multiple microprisms disposed in parallel and extending in a second direction, wherein the first direction is perpendicular to the second direction. As shown in FIG. 7a, shapes and sizes of cross sections of the multiple microprisms of the first prism layer 81 are the same as shapes and sizes of cross sections of multiple microprisms of the second prism layer 82. The prism layer of the example of FIG. 4a may be used as each of the first prism layer 81 and the second prism layer 82 in the example of FIG. 7a. Or, as shown in FIG. 7b, the multiple microprisms of the first prism layer 81 and the multiple microprisms of the second prism layer 82 each include first microprisms 8011 and second microprisms 8012 which are alternately disposed, heights of the first microprisms 8011 and the second microprisms 8012 are different, and the prism layer of the example of FIG. 5a may be used as each of the first prism layer 81 and second prism layer 82 in the example of FIG. 7b.

In some exemplary embodiments, the light of the first color is red light, the light of the second color is green light, and the light of the third color is blue light. As shown in FIG. 7c and FIG. 7d, FIG. 7c is a schematic diagram of a structure of a second light modulation layer 72 of a display substrate according to some other exemplary embodiments, and FIG. 7d is a schematic diagram of a structure of a second light modulation layer 72 of a display substrate according to some other exemplary embodiments. The second light modulation layer 72 includes a first prism layer 81 and a second prism layer 82 that are sequentially stacked in a direction away from the base substrate 10. The first prism layer 81 includes multiple microprisms disposed in parallel and extending in a first direction, the second prism layer 82 includes multiple microprisms disposed in parallel and extending in a second direction, wherein the first direction is perpendicular to the second direction. Multiple microprisms of one of the first prism layer 81 and the second prism layer 82 have the same sectional shape and size, and the multiple microprisms of the other of the first prism layer 81 and the second prism layer 82 include a first microprism 8011 and a second microprism 8012 which are disposed alternately, and heights of the first microprism 8011 and the second microprism 8012 are different. Exemplarily, in the example of FIG. 7c, the prism layer of the example of FIG. 4a may be used as the first prism layer 81 and the prism layer of the example of FIG. 5a may be used as the second prism layer 82. In the example of FIG. 7d, the prism layer of the example of FIG. 5a may be used as the first prism layer 81 and the prism layer of the example of FIG. 4a may be used as the second prism layer 82.

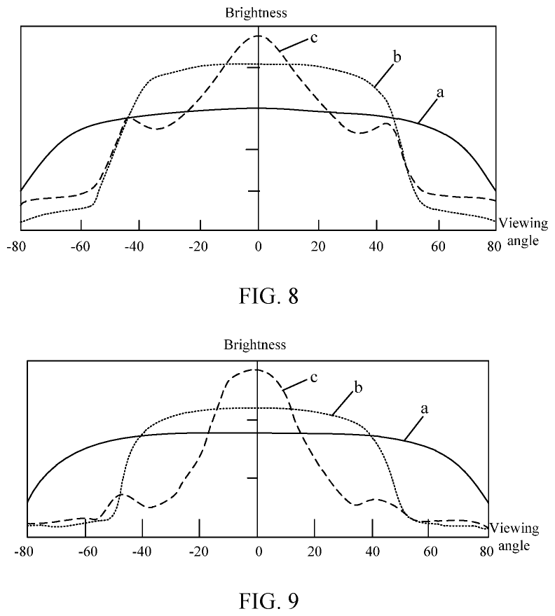

As shown in FIG. 8, FIG. 8 is a curve graph showing change of brightness with respect to a viewing angle of a display substrate according to some exemplary embodiments, and curve a represents a graph showing the change of the brightness of the display substrate with respect to the viewing angle when the first sub-pixel P1 is not provided with the first light modulation layer 71; curve b represents a graph showing the change of the brightness of the display substrate with respect to the viewing angle when the first light modulation layer 71 of the first sub-pixel P1 is provided with one prism layer; curve c represents a graph showing the change of the brightness of the display substrate with respect to the viewing angle when the first light modulation layer 71 of the first sub-pixel P1 is provided with two prism layers. As may be seen from FIG. 8, compared with the first sub-pixel P1 not provided with the first light modulation layer 71, the first light modulation layer 71 being provided with one prism layer can improve the brightness of the display substrate within a viewing angle range of −40 degrees to 40 degrees (where 0 degree is an angle perpendicular to a display surface of the display substrate, that is, the front viewing angle), and a brightness attenuation of the display substrate within the viewing angle range of −40 degrees to 40 degrees is relatively slow. Compared with the first sub-pixel P1 not provided with the first light modulation layer 71, the first light modulation layer 71 being provided with two prism layers can improve the brightness of the display substrate within a viewing angle range of −20 degrees to 20 degrees, but the brightness attenuation of the display substrate within the viewing angle range of −20 degrees to 20 degrees is relatively fast. Compared with the first light modulation layer 71 provided with one prism layer, the first light modulation layer 71 being provided with two prism layers can be more conducive to improving the brightness of the display substrate within a viewing angle range of −10 degrees to 10 degrees.

As shown in FIG. 9, FIG. 9 is a curve graph showing change of brightness with respect to a viewing angle of a display substrate according to some other exemplary embodiments, and curve a represents a graph showing the change of the brightness of the display substrate with respect to the viewing angle when the second sub-pixel P2 is not provided with the second light modulation layer 72; curve b represents a graph showing the change of the brightness of the display substrate with respect to the viewing angle when the second light modulation layer 72 of the second sub-pixel P2 is provided with one prism layer; curve c represents a graph showing the change of the brightness of the display substrate with respect to the viewing angle when the second light modulation layer 72 of the second sub-pixel P2 is provided with two prism layers. As may be seen from FIG. 9, compared with the second sub-pixel P2 not provided with the second light modulation layer 72, the second light modulation layer 72 being provided with one prism layer can improve the brightness of the display substrate within a viewing angle range of −40 degrees to 40 degrees (where 0 degree is an angle perpendicular to the display surface of the display substrate, that is, the front viewing angle), and a brightness attenuation of the display substrate within the viewing angle range of −40 degrees to 40 degrees is relatively slow. Compared with the second sub-pixel P2 not provided with the second light modulation layer 72, the second light modulation layer 72 being provided with two prism layers can improve the brightness of the display substrate within a viewing angle range of −18 degrees to 18 degrees, but the brightness attenuation of the display substrate within the viewing angle range of −18 degrees to 18 degrees is relatively fast. Compared with the second light modulation layer 72 provided with one prism layer, the second light modulation layer 72 being provided with two prism layers can be more conducive to improving the brightness of the display substrate within a viewing angle range of −15 degrees to 15 degrees.

A method for manufacturing the display substrate of the present disclosure is illustrated below. The “patterning process” mentioned herein includes processes such as film layer deposition, photoresist coating, mask exposing, developing, etching, and photoresist stripping. The deposition may be any one or more of sputtering, evaporation, and chemical vapor deposition, the coating may be any one or more of spray coating and spin coating, and the etching may be any one or more of dry etching and wet etching. A “thin film” refers to a layer of a thin film prepared from a material on a base substrate using a process of deposition or coating. If the “thin film” does not need a patterning process in an entire manufacturing process, the “thin film” may also be called a “layer”. If the “thin film” needs a patterning process in the entire manufacturing process, the “thin film” is called a “thin film” before the patterning process and is called a “layer” after the patterning process. The “layer” after the patterning process includes at least one “pattern”. “A and B are disposed in a same layer” mentioned herein, means that A and B are simultaneously formed through a same patterning process. “An orthographic projection of A includes an orthographic projection of B” means that the orthographic projection of B falls within a range of the orthographic projection of A, or the orthographic projection of A covers the orthographic projection of B.

Exemplarily, with reference to FIG. 1 to FIG. 3, a method for manufacturing the display substrate may include the following steps:

### 1) Forming a Drive Structure Layer 20 on a Base Substrate 10.

As shown in FIG. 1, a buffer thin film is deposited on a base substrate 10 and a buffer layer is formed. A semiconductor thin film is formed on the buffer layer, and a pattern of an active layer 2011 is formed by patterning the semiconductor thin film using a patterning process, and pattern of the active layer 2011 includes the active layer 2011.

A first gate insulation thin film is deposited on a side of the pattern of the active layer 2011 away from the base substrate 10 i.e., a first gate insulation layer is formed. A first gate metal thin film is deposited on a side of the first gate insulation layer away from the base substrate 10, and the first gate metal thin film is patterned using a patterning process to form a pattern of a first gate metal layer including a gate electrode 2012 and a first electrode plate 2021.

After the first gate metal layer pattern is formed, a portion of the active layer 2011 that is not covered by the gate electrode 2012 may be subjected to conductivity processing to form a first region configured to be connected to a source electrode 2013 to be subsequently formed and a second region configured to be connected to a drain electrode 2014 to be subsequently formed.

A second gate insulation thin film is deposited on a side of the first gate metal layer away from the base substrate 10 to form a second gate insulation layer. A second gate metal thin film is deposited on a side of the second gate insulation layer away from the base substrate 10, and the second gate metal thin film is patterned using a patterning process to form a second gate metal thin layer, which may include a second electrode plate 2022. The second electrode plate 2022 and the first electrode plate 2021 may correspond to each other in position and form a storage capacitor 202.

An interlayer insulation thin film is deposited on a side of the second gate metal layer away from the base substrate 10, and a first via and a second via penetrating the interlayer insulation thin film, the second gate insulation layer and the first gate insulation layer are formed by an etching process, and an interlayer insulation layer is formed.

A source-drain metal thin film is deposited on a side of the interlayer insulation layer away from the base substrate 10, and the source-drain metal thin film is patterned by a patterning process to form a source-drain metal layer. The source-drain metal layer includes a source electrode 2013 and a drain electrode 2014. The source electrode 2013 connected to a first region of the active layer 2011 through a first via and the drain electrode 2014 connected to a second region of the active layer 2011 through a second via. The source electrode 2013, the drain electrode 2014, the gate electrode 2012 and the active layer 2011 form a thin film transistor 201 (which may be a drive thin film transistor in a pixel drive circuit).

A planarization thin film of an organic material is coated on a side of the source-drain metal layer away from the base substrate 10, the planarization thin film may cover the aforementioned structures on the base substrate 10, and then a third via is formed on the planarization thin film by processes of masking, exposure, development and post-drying to expose the drain electrode 2014, thereby forming a planarization layer. At this point, manufacturing of the drive structure layer 20 is completed on the base substrate 10.

2) Forming a Light Emitting Structure Layer 30 on a Side of the Drive Structure Layer 20 Away from the Base Substrate 10.

As shown in FIG. 1, a transparent conductive thin film is deposited on the planarization layer, and a first electrode layer is formed by patterning the transparent conductive thin film using a patterning process. The first electrode layer includes multiple first electrodes 31, and the first electrodes 31 are connected to a drain electrode 2014 through the third via on the planarization layer.

A pixel definition thin film is coated on the base substrate 10 on which the aforementioned patterns are formed, and a pixel definition layer 32 is formed by processes of masking, exposure, development, and post-drying. The pixel definition layer 32 includes multiple pixel openings, each of which exposes a surface of one corresponding first electrode 31 away from the base substrate 10.

A thin film of a spacer 33 is coated on a surface of the pixel definition layer 32 away from the base substrate 10, and the thin film of the spacer 33 is patterned by a patterning process to form a spacer 33. The spacer 33 is disposed on the surface of the pixel definition layer 32 away from the base substrate 10.

The organic functional layer and the second electrode layer 37 may be sequentially formed on the base substrate 10 on which the aforementioned patterns are formed, by an evaporation process. The organic functional layer may include a first organic structure layer 34, an organic light emitting layer 35, and a second organic structure layer 36 that are sequentially stacked. The first organic structure layer 34 may include a hole injection layer, a hole transport layer, and an electron barrier layer that are sequentially stacked, and the second organic structure layer 36 may include a hole barrier layer, an electron transport layer, and an electron injection layer that are sequentially stacked. Any one film layer of the first organic structure layer 34 and the second organic structure layer 36 has an integral structure and is a common layer of multiple sub-pixels (or multiple light emitting devices 301), and the organic light emitting layer 35 has an integral structure and is a common layer of multiple sub-pixels (or multiple light emitting devices 301). Each of the first electrodes 31, the organic functional layer and the second electrode layer 37 are sequentially stacked to form one of the light emitting devices 301. In a process of forming any one film layer of the first organic structure layer 34 and the second organic structure layer 36 as well as the organic light emitting layer 35 by an evaporation process, an open mask may be used for formation.

3) Forming a First Encapsulation Structure Layer 40 on a Side of the Light Emitting Structure Layer 30 Away from the Base Substrate 10.

A first inorganic encapsulation layer 41, an organic encapsulation layer 42, and a second inorganic encapsulation layer 43 are sequentially formed on the base substrate 10 on which the aforementioned patterns are formed, thereby forming a first encapsulation structure layer 40. Among them, the first inorganic encapsulation layer 41 and the second inorganic encapsulation layer 43 may be formed by a chemical vapor deposition process, and the first inorganic encapsulation layer 41 and the second inorganic encapsulation layer 43 may have a single-layer structure or a multi-layer structure. The organic encapsulation layer 42 may be formed using an ink jet printing process.

In the examples of FIG. 1 and FIG. 3, a material of the organic encapsulation layer 42 includes a mixed material of an organic encapsulation material and a dye and the material of the organic encapsulation layer 42 of each sub-pixel is the same. After the first encapsulation structure layer 40 is formed using a chemical vapor deposition process, the organic encapsulation layer 42 of the example of FIG. 1 and FIG. 3 is formed using an ink-jet printing process. The organic encapsulation material and the dye may be included in ink of an ink-jet printer during the formation of the organic encapsulation layer 42.

In the example of FIG. 2, a first groove, a second groove, and a third groove may be formed on a surface of the first encapsulation thin film away from the base substrate 10 by an etching process after the first inorganic encapsulation thin film is formed by using a chemical vapor deposition process, thereby forming the first inorganic encapsulation layer 41. Thereafter, a first mixed material 421 including the organic encapsulation material and a first dye is formed in the first groove by an ink-jet printing process, a second mixed material 422 including the organic encapsulation material and a second dye is formed in the second groove, and a third mixed material 423 including the organic encapsulation material and a third dye is formed in the third groove, and the mixed material layer is formed after the first mixed material 421, the second mixed material 422 and the third mixed material 423 are standing and leveled, and cured by physical sedimentation and ultraviolet light (UV). Thereafter, a film layer formed of the organic encapsulation material is formed on a side of the mixed material layer away from the base substrate 10 using an ink jet printing process. Thereafter, the second inorganic encapsulation layer 43 is formed using a chemical vapor deposition process.

4) Forming a Light Conversion Layer on a Side of the First Encapsulation Structure Layer 40 Away from the Base Substrate 10.

In the examples of FIG. 1 and FIG. 2, a first black matrix thin film may be formed on the base substrate 10 on which the aforementioned patterns are formed, and a first black matrix layer 51 may be formed by patterning the first black matrix thin film using a photolithography process. The first black matrix layer 51 is provided with multiple first openings, each of the first openings and the light emitting device 301 of each corresponding sub-pixel are disposed oppositely. Thereafter, a first quantum dot layer 521 located in the first opening of the first sub-pixel P1, a second quantum dot layer 522 located in the first opening of the second sub-pixel P2, and a light transmissive layer 523 located in the first opening of the third sub-pixel P3 may be formed using printing or spin coating processes respectively. Among them, the light conversion layer includes the first quantum dot layer 521 located in the first sub-pixel P1, the second quantum dot layer 522 located in the second sub-pixel P2, and the light transmissive layer 523 located in the third sub-pixel P3.

In the example of FIG. 3, a light conversion layer 52 may be formed on the base substrate 10 on which the aforementioned patterns are formed using a printing or spin coating process. The light conversion layer 52 has an integral structure, and a material of the light conversion layer 52 includes a first quantum dot material and a second quantum dot material.

5) Forming a Second Encapsulation Structure Layer 53 on a Side of the Light Conversion Layer Away from the Base Substrate 10.

As shown in FIG. 1, the second encapsulation structure layer 53 may be formed on the base substrate 10 on which the aforementioned pattern is formed using a chemical vapor deposition process. A material of the second encapsulation structure layer 53 may be an inorganic material and the second encapsulation structure layer 53 may be in a single layer structure or a multi-layer structure.

6) Forming a Color Filter Layer on a Side of the Second Encapsulation Structure Layer 53 Away from the Base Substrate 10.

As shown in FIG. 1, a second black matrix thin film may be formed on the base substrate 10 on which the aforementioned patterns are formed, and a second black matrix layer 61 may be formed by patterning the second black matrix film using a photolithography process. The second black matrix layer 61 is provided with multiple second openings, each of the second openings and the light emitting device 301 of each corresponding sub-pixel are disposed oppositely. Thereafter, a spin coating process or a photolithography process may be used to form a first filter unit 621 within the second opening of the first sub-pixel P1, a second filter unit 622 within the second opening of the second sub-pixel P2, and a third filter unit 623 within the second opening of the third sub-pixel P3. Among them, the color filter layer includes the first filter unit 621, the second filter unit 622, and the third filter unit 623.

7) Forming a Light Modulation Layer on a Side of the Color Filter Layer Away from the Base Substrate 10.

As shown in FIG. 1, a first light modulation layer 71 is formed on a side of the first light filter unit 621 away from the base substrate 10 and a second light modulation layer 72 is formed on a side of the second light filter unit 622 away from the base substrate 10. The first light modulation layer 71 and the second light modulation layer 72 each include at least one prism layer.

Based on the above contents, an embodiment of the present disclosure further provides a method for manufacturing a display substrate, including:
forming a drive structure layer on a base substrate, wherein the drive structure layer includes a pixel drive circuit;
forming multiple light emitting devices emitting light of a third color on a side of the drive structure layer away from the base substrate, wherein the light emitting devices are electrically connected with the pixel drive circuit;
forming a first inorganic encapsulation layer, an organic encapsulation layer and a second inorganic encapsulation layer sequentially on a side of the multiple light emitting devices away from the base substrate; wherein the organic encapsulation layer includes an organic encapsulation material and a dye, a color of the dye is the same as that of the light of the third color emitted by the light emitting devices, and a peak wavelength of emergent light of the third color after the light of the third color emitted by the light emitting devices passes through the organic encapsulation layer is different from a peak wavelength of the light of the third color emitted by the light emitting devices; and the organic encapsulation layer is formed by an ink jet printing process;
a light conversion layer is formed on a side of the second inorganic encapsulation layer away from the base substrate, wherein the light conversion layer is configured to emit light of a first color and light of a second color after receiving the light of the third color emitted by the multiple light emitting devices, the light conversion layer includes a first quantum dot material and a second quantum dot material, the first quantum dot material is configured to emit light of the first color after receiving the light of the third color emitted by the light emitting devices, and the second quantum dot material is configured to emit light of second color after receiving the light of the third color emitted by the light emitting devices.

An embodiment of the present disclosure further provides a display device, which includes the display substrate according to any one of the previous embodiments. The display device may be any product or component with a display function, such as a mobile phone, a tablet computer, a television, a display, a laptop computer, a digital photo frame, and a navigator.

In the accompanying drawings, a size of a constituent element, and a thickness of a layer or an area are sometimes exaggerated for clarity. Therefore, an implementation of the present disclosure is not necessarily limited to the size, and the shape and size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus also includes a state in which the angle is above −5° and below 5°. In addition, “vertical” refers to a state in which an angle formed by two straight lines is above 80° and below 100°, and thus also includes a state in which the angle is above 85° and below 95°.

In the description herein, orientation or position relationships indicated by terms such as “upper”, “lower”, “left”, “right”, “top”, “inside”, “outside”, “axial”, “tetragonal” and the like are orientation or position relationships shown in the drawings, and are intended to facilitate description of the embodiments of the present disclosure and simplification of the description, but not to indicate or imply that the mentioned structure has a specific orientation or be constructed and operated in a specific orientation, therefore, they should not be understood as limitations on the present disclosure.

In the description herein, unless otherwise specified and defined explicitly, terms “connection”, “fixed connection”, “installation” and “assembly” should be understood in a broad sense, and, for example, a connection may be a fixed connection, a detachable connection or an integrated connection. The terms “installation”, “connection” and “fixed connection” may be a direct connection, an indirect connection through intermediate components, or an inner communication between two elements. For those ordinarily skilled in the art, meanings of the above terms in the embodiments of the present disclosure may be understood according to situations.

1. A display substrate, comprising a first sub-pixel with emergent light of a first color, a second sub-pixel with emergent light of a second color, and a third sub-pixel with emergent light of a third color disposed on the base substrate;
the display substrate comprises a plurality of light emitting devices disposed on the base substrate for emitting light of the third color, and a first encapsulation structure layer and a light conversion layer which are sequentially stacked on a side of the plurality of light emitting devices away from the base substrate, and each sub-pixel comprises one of the light emitting devices;
the light conversion layer is configured to emit the light of the first color and the light of the second color after receiving the light of the third color emitted by the plurality of light emitting devices, the light conversion layer comprises a first quantum dot material and a second quantum dot material, the first quantum dot material is configured to emit the light of the first color after receiving the light of the third color emitted by the light emitting devices, and the second quantum dot material is configured to emit the light of the second color after receiving the light of the third color emitted by the light emitting devices;
the first encapsulation structure layer comprises a first inorganic encapsulation layer, an organic encapsulation layer, and a second inorganic encapsulation layer that are sequentially stacked in a direction away from the base substrate; the organic encapsulation layer comprises an organic encapsulation material and a dye, a color of the dye is the same as a color of the light of the third color emitted by the light emitting devices, and a peak wavelength of emergent light of the third color after the light of the third color emitted by the light emitting devices passes through the organic encapsulation layer is different from a peak wavelength of the light of the third color emitted by the light emitting devices.

2. The display substrate according to claim 1, wherein the light conversion layer has an integral structure; or, the light conversion layer comprises a first quantum dot layer located in the first sub-pixel, a second quantum dot layer located in the second sub-pixel, and a light transmissive layer located in the third sub-pixel; the first quantum dot layer is configured to emit the light of the first color after receiving light of the third color emitted by a light emitting device of the first sub-pixel, the second quantum dot layer is configured to emit light of the second color after receiving light of the third color emitted by a light emitting device of the second sub-pixel, and the light transmissive layer is configured to emit light of the third color after the light of the third color emitted by a light emitting device of the third sub-pixel passes through the light transmissive layer.

3. The display substrate according to claim 2, wherein a material of the organic encapsulation layer comprises a mixed material of the organic encapsulation material and the dye, and a material of the organic encapsulation layer of each sub-pixel is the same.

4. The display substrate according to claim 2, wherein the light conversion layer comprises the first quantum dot layer located within the first sub-pixel, the second quantum dot layer located within the second sub-pixel, and the light transmissive layer located within the third sub-pixel; and
the organic encapsulation layer comprises a first dye in the first sub-pixel, a second dye in the second sub-pixel, and a third dye in the third sub-pixel; a peak wavelength of emergent light of the third color after the light of the third color emitted by the light emitting device of the first sub-pixel passes through the organic encapsulation layer of the first sub-pixel is λ1, a peak wavelength of emergent light of the third color after the light of the third color emitted by the light emitting device of the second sub-pixel passes through the organic encapsulation layer of the second sub-pixel is λ2, and a peak wavelength of emergent light of the third color after the light of the third color emitted by the light emitting device of the third sub-pixel passes through the organic encapsulation layer of the third sub-pixel is λ3, wherein λ1, λ2 and λ3 are not equal to each other.

5. The display substrate according to claim 4, wherein a surface of the first inorganic encapsulation layer away from the base substrate is provided with a first groove in the first sub-pixel, a second groove in the second sub-pixel, and a third groove in the third sub-pixel;
the organic encapsulation layer comprises a mixed material layer, the mixed material layer comprises a first mixed material disposed in the first groove, a second mixed material disposed in the second groove, and a third mixed material disposed in the third groove, the first mixed material comprises the organic encapsulation material and the first dye, the second mixed material comprises the organic encapsulation material and the second dye, and the third mixed material comprises the organic encapsulation material and the third dye.

6. The display substrate according to claim 5, wherein the organic encapsulation layer further comprises a film layer formed of the organic encapsulation material disposed on a side of the mixed material layer away from the base substrate.

7. The display substrate according to claim 1, further comprising a color filter layer disposed on a side of the light conversion layer away from the base substrate, the color filter layer comprises a first filter unit located in the first sub-pixel, a second filter unit located in the second sub-pixel, and a third filter unit located in the third sub-pixel; the first filter unit is configured to filter and emit the light of the first color, the second filter unit is configured to filter and emit the light of the second color, and the third filter unit is configured to filter and emit the light of the third color.

8. The display substrate according to claim 7, further comprising a light modulation layer disposed on a side of the color filter layer away from the base substrate, the light modulation layer comprises a first light modulation layer in the first sub-pixel and a second light modulation layer in the second sub-pixel, each of the first light modulation layer and the second light modulation layer comprises at least one prism layer, the at least one prism layer is configured to converge light emitted from the color filter layer of a sub-pixel where the prism layer is located toward a direction of a front viewing angle of the display substrate.

9. The display substrate according to claim 8, wherein the prism layer comprises a plurality of microprisms disposed in parallel; shapes and sizes of cross sections of the plurality of microprisms are the same, or the plurality of microprisms comprise first microprisms and second microprisms which are disposed alternately, and heights of the first microprisms and second microprisms are different.

10. The display substrate according to claim 8, wherein the light of the first color is red light, the light of the second color is green light, and the light of the third color is blue light;
the first light modulation layer comprises a first prism layer and a second prism layer that are sequentially stacked in the direction away from the base substrate, the first prism layer comprises a plurality of microprisms disposed in parallel and extending in a first direction, the second prism layer comprises a plurality of microprisms disposed in parallel and extending in a second direction, the first direction is perpendicular to the second direction; shapes and sizes of cross sections of the plurality of microprisms of the first prism layer are the same as shapes and sizes of the plurality of microprisms of the second prism layer, or the plurality of microprisms of the first prism layer and the plurality of microprisms of the second prism layer each comprise first microprisms and second microprisms which disposed alternately, and heights of the first microprisms and the second microprisms are different.

11. The display substrate according to claim 8, wherein the light of the first color is red light, the light of the second color is green light, and the light of the third color is blue light;
the first light modulation layer comprises a first prism layer and a second prism layer stacked sequentially in the direction away from the base substrate, the first prism layer and the second prism layer each comprise a plurality of microprisms disposed in parallel and extending in a first direction; a plurality of microprisms of one of the first prism layer and the second prism layer have the same cross-sectional shape and size, and a plurality of microprisms of the other of the first prism layer and the second prism comprise first microprisms and second microprisms which are disposed alternately, and heights of the first microprisms and the second microprisms are different.

12. The display substrate according to claim 8, wherein the light of the first color is red light, the light of the second color is green light, and the light of the third color is blue light;
the second light modulation layer comprises a first prism layer and a second prism layer stacked sequentially in the direction away from the base substrate, the first prism layer comprises a plurality of microprisms disposed in parallel and extending in a first direction, the second prism layer comprises a plurality of microprisms disposed in parallel and extending in a second direction, the first direction is perpendicular to the second direction; shapes and sizes of cross sections of the plurality of microprisms of the first prism layer are the same as shapes and sizes of the plurality of microprisms of the second prism layer, or the plurality of microprisms of the first prism layer and the plurality of microprisms of the second prism layer each comprise first microprisms and second microprisms which are disposed alternately, and heights of the first microprisms and the second microprisms are different.

13. The display substrate according to claim 8, wherein the light of the first color is red light, the light of the second color is green light, and the light of the third color is blue light;
the second light modulation layer comprises a first prism layer and a second prism layer stacked sequentially in the direction away from the base substrate, the first prism layer comprises a plurality of microprisms disposed in parallel and extending in a first direction, the second prism layer comprises a plurality of microprisms disposed in parallel and extending in a second direction, the first direction is perpendicular to the second direction; a plurality of microprisms of one of the first prism layer and the second prism layer have the same cross-sectional shape and size, and a plurality of microprisms of the other of the first prism layer and the second prism comprise first microprisms and second microprisms which are disposed alternately, and heights of the first microprisms and the second microprisms are different.

14. The display substrate according to claim 9, wherein the shapes and sizes of the cross sections of the plurality of microprisms are the same, a cross-sectional shape of each of the microprisms is an isosceles triangle, the isosceles triangle has an apex angle of 60° to 120°, bottom edge length of 20 um to 30 um, and a height of 12 um to 18 um.

15. The display substrate according to claim 9, wherein the plurality of microprisms comprise first microprisms and second microprisms which are disposed alternately, and a cross-sectional shape of each of the first microprisms and the second microprisms is an isosceles triangle; the isosceles triangle of the cross sections of the first microprisms has an apex angle of 60° to 120°, a bottom edge length of 20 um to 32 um, and a height of 12 um to 18 um; the isosceles triangle of the cross sections of the second microprisms has an apex angle of 60° to 120°, a bottom edge length of 14 um to 22 um, and a height of 7 um to 12 um.

16. The display substrate according to claim 7, further comprising a second encapsulation structure layer disposed between the light conversion layer and the color filter layer, wherein a material of the second encapsulation structure layer is an inorganic material.

17. The display substrate according to claim 1, wherein the light emitting devices are blue organic light emitting diode devices, the light of the third color is blue light, the light of the first color is red light, and the light of the second color is green light.

18. A display device, comprising the display substrate according to claim 1.

19. A method for manufacturing a display substrate, comprising:
forming a drive structure layer on a base substrate, wherein the drive structure layer comprises a pixel drive circuit;
forming a plurality of light emitting devices emitting light of a third color on a side of the drive structure layer away from the base substrate, the light emitting devices are electrically connected with the pixel drive circuit;
forming a first inorganic encapsulation layer, an organic encapsulation layer and a second inorganic encapsulation layer sequentially on a side of the plurality of light emitting devices away from the base substrate; wherein the organic encapsulation layer comprises an organic encapsulation material and a dye, a color of the dye is the same as a color of the light of the third color emitted by the light emitting devices, and a peak wavelength of emergent light of the third color after the light of the third color emitted by the light emitting devices passes through the organic encapsulation layer is different from a peak wavelength of the light of the third color emitted by the light emitting devices; the organic encapsulation layer is formed by an ink jet printing process; and
a light conversion layer is formed on a side of the second inorganic encapsulation layer away from the base substrate, wherein the light conversion layer is configured to emit the light of the first color and the light of the second color after receiving the light of the third color emitted by the plurality of light emitting devices, the light conversion layer comprises a first quantum dot material and a second quantum dot material, the first quantum dot material is configured to emit the light of the first color after receiving the light of the third color emitted by the light emitting devices, and the second quantum dot material is configured to emit the light of the second color after receiving the light of the third color emitted by the light emitting devices.

20. A display device, comprising the display substrate according to claim 2.
